(19) United States
(12) Patent Application Publication
(10) Pub. No.: US 2026/0050722 A1
(43) Pub. Date: Feb. 19, 2026

(54) OPTIMIZATION OF VIA MESH SPECIFICATIONS IN AN INTEGRATED CIRCUIT

(71) Applicant: International Business Machines Corporation, Armonk, NY (US)

(72) Inventors: Joseph Koone, Poughkeepsie, NY (US); David Brian Schreck, Poughkeepsie, NY (US); Alexander Joel Suess, Hopewell Junction, NY (US); William Edward Dougherty, JR., Pittsburgh, PA (US); Adam P. Matheny, Hyde Park, NY (US); Smitha Reddy, Fishkill, NY (US)

(21) Appl. No.: 18/804,326

(22) Filed: Aug. 14, 2024

(51) Int. Cl. G06F 30/3308; G06F 30/333

(52) U.S. Cl. CPC G06F 30/3308; G06F 30/333

(57) ABSTRACT

Aspects of the invention include optimization of via mesh specifications in an integrated circuit. Aspects include obtaining a first mesh specification for a cell within an integrated circuit, identifying, based on a simulation of a first via mesh built based on the first via mesh specification, portions of the first mesh specification for enhancement, and generating a second mesh specification for the cell, wherein the second mesh specification is different from the first mesh specification. Aspects also include generating a second via mesh based on the second via mesh specification, updating a design of the integrated circuit by replacing the first via mesh with the second via mesh and connecting a top layer of the second via mesh to the net, and saving the updated design of the integrated circuit based on a determination that the updated design of the integrated circuit passes a timing and design rule check.

### BACKGROUND

The present invention generally relates to integrated circuit development, and more specifically, to the optimization of via mesh specifications in an integrated circuit.

The development of an integrated circuit (i.e., chip) involves several stages from design through fabrication. Some aspects of the development are performed iteratively to ensure that the chip that is ultimately manufactured meets all design requirements. In addition, aspects of the design may be performed in a hierarchical manner. An exemplary organization of a chip is as a set of interconnected cells. Each cell includes a number of interconnected components that allow the cell to serve a specific function (e.g., OR gate, NAND gate). Cells may be standard cells selected from a library to perform a specific function.

The interconnection of cells is through wires routed over multiple levels (i.e., metal layers) with vias (i.e., vertical interconnections) facilitating connections among the stacked metal layers. Timing of the chip may be improved by using higher level metal layers that can carry thicker metal wires. However, this timing improvement must be balanced with the increased density that would result from routing too many interconnections at higher metal layers. This is because increased density increases interference and negatively affects chip performance. Each cell may have different pin layouts and different placement options in relation to the power grid of the particular chip. Placement refers to the particular location within the chip and affects routability. Routing refers to the path (e.g., wire widths, metal layers) used for the interconnection. A cell is not routable if, based on a particular placement, it cannot be interconnected with other cells in a way that meets timing, power, and other requirements.

### SUMMARY

Embodiments of the present invention are directed to methods for optimization of via mesh specifications during integrated circuit development. A non-limiting example computer-implemented method includes obtaining, using a processor, a first mesh specification for a cell within an integrated circuit, the first mesh specification defining one or more straps on each layer above a first layer, which includes one or more pins that form a pin terminal, to a top layer that connects the cell to a net for interconnection of the cell with one or more other cells, and the via mesh specification also including one or more vias that interconnect adjacent ones of the layers. The method also includes identifying, using the processor based on a simulation of a first via mesh built based on the first via mesh specification, one or more portions of the first mesh specification for enhancement, generating, by the processor, a second mesh specification for the cell, wherein the second mesh specification is different from the first mesh specification, and generating, by the processor, a second via mesh based on the second via mesh specification. The method further includes updating, by the processor, a design of the integrated circuit by replacing the first via mesh with the second via mesh and connecting a top layer of the second via mesh to the net and saving the updated design of the integrated circuit based on a determination that the updated design of the integrated circuit passes a timing and design rule check.

Other embodiments of the present invention implement features of the above-described computer systems and computer program products for the optimization of via mesh specifications during integrated circuit development.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 illustrates a computing environment according to one or more embodiments;

FIG. 2A illustrates a three-dimensional representation of a via mesh according to one or more embodiments of the invention;

FIG. 2B illustrates a representation of a via mesh specification for the exemplary via mesh shown in FIG. 2A according to one or more embodiments of the invention;

FIG. 3 is a process flow of a method of generating via mesh specifications according to embodiments of the invention;

FIG. 4 shows an exemplary net that forms a logical connection between the input pins of one cell and the output pins of another cell according to exemplary embodiments of the invention;

FIG. 5 is a process flow of a method of assigning pin constraints that facilitate selection from among universally routable via mesh specifications according to one or more embodiments of the invention;

FIG. 6 is a process flow of a method of selecting a via mesh as part of an optimization process according to one or more embodiments of the invention;

FIGS. 7A and 7B illustrate representations of a via mesh specification for an exemplary via mesh before and after the optimization of the via mesh specification according to one or more embodiments of the invention;

FIG. 8 is a process flow of a method of optimizing a via mesh specification according to one or more embodiments of the invention;

FIG. 9 is a block diagram of a system to perform circuit design optimization according to one or more embodiments; and

FIG. 10 is a flow diagram of a method of fabricating an integrated circuit according to one or more embodiments.

The diagrams depicted herein are illustrative. There can be many variations to the diagrams or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

### DETAILED DESCRIPTION

As previously noted, the cells that make up a chip are interconnected to perform the overall functionality of the chip. Each cell involves an interconnection of components that, together, perform the function of that cell (e.g., multiplication, AND gate). A via mesh provides multiple conductive pathways from one or more points in one layer to one or more points in another layer. At the first level, the via mesh includes interconnected shapes (i.e., wires and vias) that connect to a pin terminal comprised of a single pin or a set of disjoint pins that are logically treated as one pin. On each subsequent layer, one or more straps, which are conductive strips, form conductive pathways that are connected to straps on adjacent layers through one or more vias. While the straps within a layer are oriented parallel to each other, the straps of adjacent layers may be oriented in a different (e.g., orthogonal) direction relative to each other or may be parallel. A router that connects one or more pins of the cell to pins of other cells, which may or may not include a via mesh, only connects to the strap at the highest level of the via mesh. The number of layers from the one or more pins to the highest level defines the height of the via mesh. The redundancy afforded by the straps and vias results in a reduction in resistance of the connection from the one or more pins to the upper layers. The number of straps and vias determines the resistance. A decrease in resistance is referred to as an increase in strength of the via mesh.

A via mesh specification provides a via mesh router with the required number of straps and vias for each metal layer of the cell. That is, a via mesh specification defines the via mesh structure and indicates the via mesh height. A given cell may have more than one via mesh specification associated with it, and each via mesh specification may offer a different resistance and corresponding strength.

Embodiments of the invention relate to the optimization of a via mesh for an integrated circuit. In exemplary embodiments, placement and routing of the straps in a via meshes in the integrated circuit, the circuit design is tested to identify potential timing or electromigration issues in the integrated circuit design. Once the potential timing or electromigration issues are identified, a new via mesh specification is created for the via mesh that includes the identity timing or electromigration issues. In exemplary embodiments, the new via mesh specification is provided to a router to build a new via mesh based on the new mesh specification. Next, the design of the integrated circuit having the new via mesh is checked to ensure compliance with design rules and the timing constraints. Based on a determination that the design of the integrated circuit having the new via mesh is in compliance with design rules and the timing constraints, the existing via mesh is replaced with the new via mesh.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

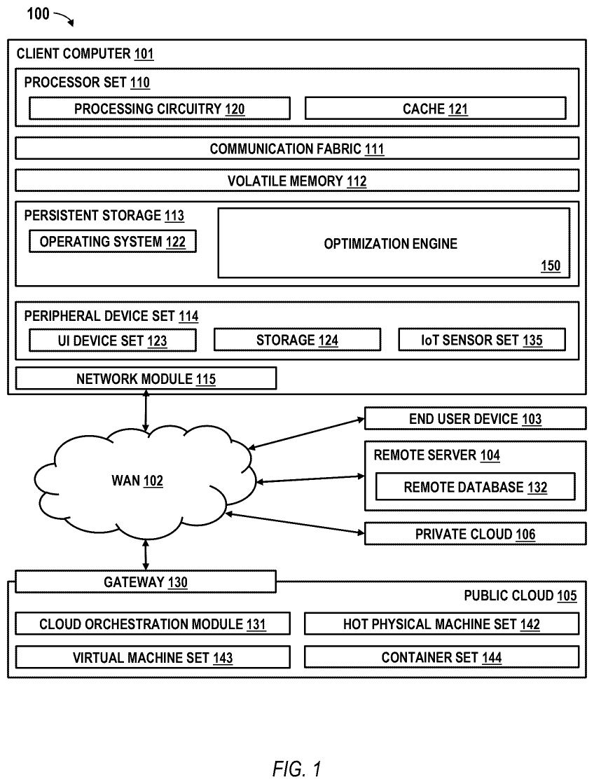

FIG. 1 illustrates a computing environment 100, according to an embodiment. Computing environment 100 contains an example of an environment for the execution of at least some of the computer code involved in performing the inventive methods, such as an optimization engine 150 for performing optimization of via mesh specifications during integrated circuit development. In addition to optimization engine 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and optimization engine 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in optimization engine 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in optimization engine 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

According to one or more embodiments, the computing environment 100 can provide for remote data storage. For example, the computer 101 can be a cloud storage system or other suitable system for storing data that is accessible to a user remotely, such as by accessing the computer 101 using the end user device 103. That is, a user can send a user operation (also referred to as a “user request”) from the end user device 103 to the computer 101 via the WAN 102. Although the user operation may appear to be simple, such as uploading an object to a cloud storage system, the complications of operating a cloud computing system often have side effects and produce ancillary data, which may be consumed by both the operator of the system (e.g., the computer 101) and by users or other components of the cloud architecture (e.g., the computing environment 100). Ancillary data may be created by user operations that trigger the creation of the ancillary data. Ancillary data may be resource consumption information, notification data, and/or the like, including combinations and/or multiples thereof. Data for an independent event may be inferred from another event (e.g., event to update resource consumption information for an entity in a system also means that the total consumption information for the oner of the entity is also updated).

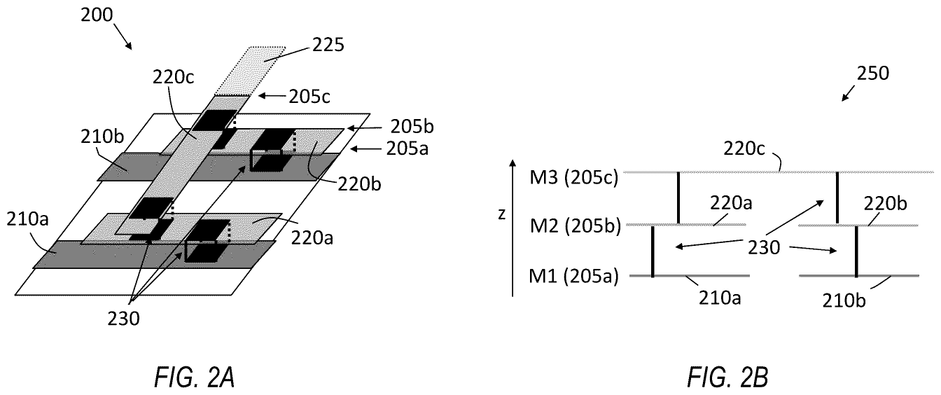

FIGS. 2A and 2B illustrate an exemplary via mesh 200 for an exemplary cell 125 and a corresponding representation associated with the via mesh specification 250 that is generated according to one or more embodiments of the invention. FIG. 2A shows a three-dimensional representation of the via mesh 200. Pins 210a, 210b (generally referred to as 210) are shown on the first layer 205a (generally referred to as 205). Straps 220a, 220b (generally referred to as 220) are shown on the second layer 205b. As FIG. 2A indicates, the pins 210 and straps 220 are parallel and a via 230 connects each pin 210 to a corresponding strap 220. As previously noted, the pins 210 and straps 220 on adjacent layers may be oriented differently (e.g., orthogonal), instead. Another strap 220c is shown at the third layer 205c, which is the top layer of the exemplary via mesh structure 200. The strap 220c on the third layer 205c is orthogonal to the straps 220a, 220b on the second layer 205b. The number of layers 205 defines the height of the via mesh 200.

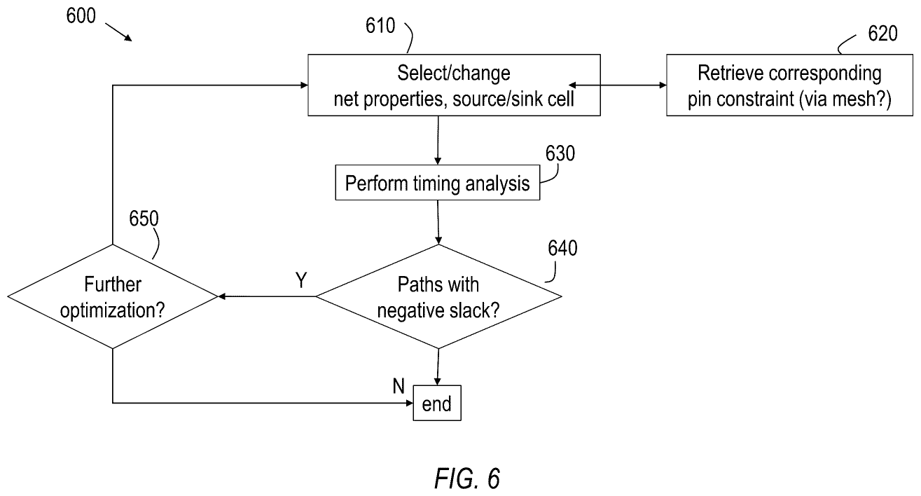

Vias 230 facilitate a connection between the pins 210 on the first layer 205a and the straps 220a and 220b on the second layer 205b and additional vias facilitate a connection between each of the straps 220a and 220b on the second layer 205b and the strap 220c at the third layer 205c. The straps 220 and vias 230 make up the via mesh 200. A routing tool, referred to as a router, connects the pins 210 of the cell 125, through the via mesh 200 of the cell 125, to one or more other cells 125 through a net 400 (FIG. 6). Specifically, the router connects the cell 125 to the net 400 only at the top level 205 (i.e., the third layer 205c in the example shown) at the access 225. As previously noted, the via mesh 200 (e.g., the straps 220 and vias 230) provides redundancy in the connection from the net 400 to the pins 210. Increased redundancy is proportional to increased strength of the via mesh 200 and decreased resistance.

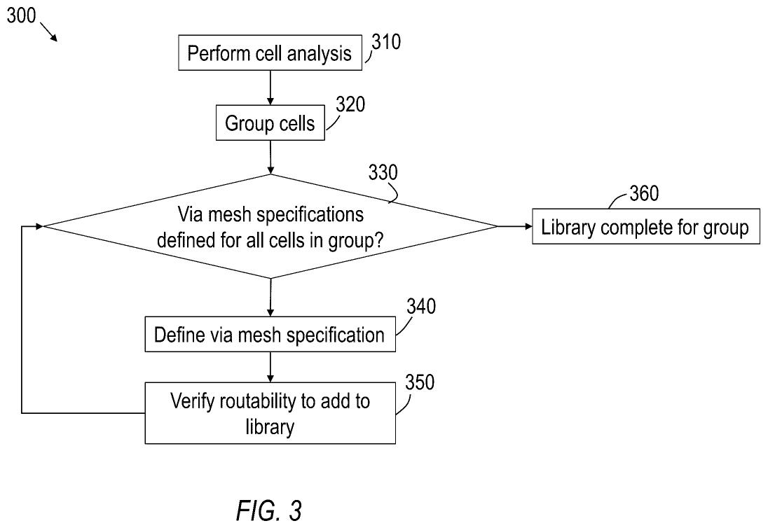

FIG. 2B shows a representation of a via mesh specification 250 that is generated for the exemplary via mesh 200 shown in FIG. 2A according to one or more embodiments of the invention. The via mesh specification 250 defines the structure of the via mesh 200 and provides the router with wire and via counts for each layer 205. The exemplary via mesh specification 250, as represented in FIG. 2B, indicates that there are two pins 210 on the first layer 205a (i.e., metal layer 1 (M1)) that are connected by respective vias 230 to two straps 220 on the second layer 205b (i.e., metal layer 2 (M2)). Additional vias 230 allow a strap 220c on the third layer 205c (i.e., metal layer 3 (M3)) to connect to both straps 220 on the second layer 205b and, thereby, to both pins 210 on the first layer 205a. The number of straps 220 (2) on M2 and the number of straps 220 (1) on M3 may be used to represent the via mesh specification 250 as {2,1}. This indicates the number of metal layers and, thus, the height of the via mesh 200 as being 3, and also specifies the number of straps 220 on the second and every subsequent layer 205. As previously noted, exemplary embodiments of the invention relate to generating a library of via mesh specifications 250 that are each guaranteed to be routable regardless of the placement of the cell 200. This routability is further discussed with reference to FIGS. 3-5.

FIG. 3 is a process flow of a method 300 of generating universally routable via mesh specifications 250 according to embodiments of the invention. At block 310, performing cell analysis refers to gathering statistics for each cell 200 including the number of input terminals, the number of input pins 210, the number of output terminals, the number of output pins 210, the cell width, and the cell height. A pin terminal refers to the logical representation of one or more pins 210. That is, a pin terminal may represent a single pin 210 or a disjoint set of pins 210 that are logically treated as one. At block 320, grouping cells 125 may be based on different cell statistics. For example, cells 125 may be grouped according to the number of output pins 210 versus the cell height, the number of input pins 210 versus the cell height, or the number of output terminals versus the number of input terminals. At block 330, a determination is made whether via mesh specifications 250 were defined for the group in consideration of all the cells 125 of the group. If so, then the method 300 ends at block 360 with a complete library of via mesh specifications 250 that are compatible with any of the cells 200 of the group. If not, the processes at blocks 340 and 350 are performed iteratively, as indicated.

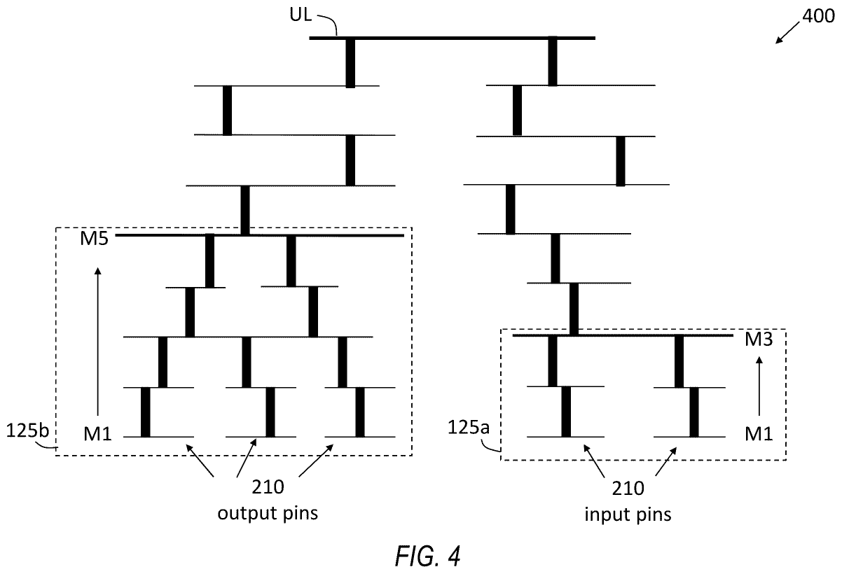

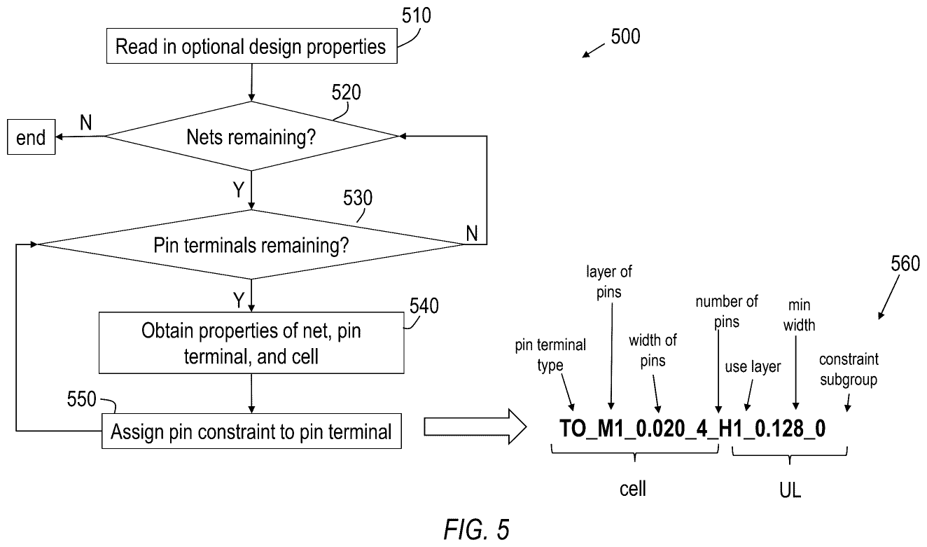

At block 340, defining a via mesh specification 250 includes obtaining a resistance estimation for each via mesh specification 250 that is generated. The maximum strength via mesh 200 may be created for each group of cells 125 and lower strength options for the via mesh 200 may then be derived. At block 350, verifying routability results in only universally routable (i.e., routable regardless of placement) via mesh specifications 250 being retained in the library. Routability refers to the cell 125 being interconnectable to other cells 125 through a net 400 while meeting all design rules. Generally, individual placement and packed placement scenarios are considered for each cell 125, as further discussed with reference to FIGS. 4 and 5. Any via mesh 200 that is deemed not to be universally routable is eliminated from the via mesh specification library entries for the group of cells 125.

As FIG. 3 indicates, defining via mesh specifications (at block 340) and verifying routability (at block 350) are performed iteratively until all via mesh options for all cells 125 of a group are considered. The routability determination does not require actual layout of a given via mesh 200. Thus, a large number of via mesh options with a variety of strengths and heights may be tested for routability according to one or more embodiments of the invention. Only via mesh specifications 250 that are routable regardless of placement are retained in the library (at block 360).

Referring now to FIG. 4, an exemplary net 400 that forms a logical connection between the input pins 210 of one cell 125a and the output pins 210 of another cell 125b according to exemplary embodiments of the invention is shown. The exemplary cells 125a and 125b are both shown with representations of via mesh specifications 250. However, only one of the cells 125 may have a via mesh 200 according to alternate embodiments of the invention. A wire code (WC) indicates constraints that are placed on the net 400. The WC may indicate minimum wire width and spacing, for example. The width is based on timing criticality, with more critical nets having a higher minimum wire width. The use layer (UL) is a constraint on the net 400 that indicates the longest wire and the one that interconnects the two portions of the net 400 that each connect to one of the cells 125a, 125b, as indicated. The UL may be a range of layers 205 or a single layer 205, as shown in the exemplary case. The UL is generally at a higher layer 205 based on increased timing criticality of a net 400.

As FIG. 4 illustrates, connecting input pins 210 of one cell 125a with output pins 210 of another cell 125b requires not only the net 400 but also the via mesh 200 of one or both of the cells 125. The via mesh 200 for a cell 125 is selected from among the available universally routable via mesh specifications 250 that are generated according to one or more embodiments of the invention and stored in the library for the group to which the cell 125 belongs. The selected via mesh 200 must be suited to the net 400 in consideration of both timing and routing congestion. As further discussed with reference to FIGS. 5 and 6, the pin terminal constraints, referred to as pin constraints 560 (FIG. 5) and created to indicate net specifications, may be modified to also indicate the via mesh specification 250 to be selected from the library according to one or more embodiments of the invention. That is, each pin constraint 560 includes information pertaining to a corresponding via mesh specification 250. That corresponding via mesh specification 250 may or may not be among the universally routable via mesh specifications 250 in the library that is populated at block 360, as further discussed with reference to FIG. 6.

FIG. 5 is a process flow of a method 500 of assigning pin constraints 560 that facilitates selection from among universally routable via mesh specifications 250 according to one or more embodiments of the invention. Once the structure of the net 400 is defined, the processes shown in FIG. 5 may be performed at any time. At block 510, reading in optional design properties refers to design properties that may limit the strength of the via mesh 200 that may be used. At block 520, a check is done of whether nets 400 that interconnect cells 125 remain without already having been processed to assign pin constraints 560. If not, then the process flow is completed, as indicated. If the check at block 520 indicates that there is at least one net 400 that has not yet been processed, the check at block 530 is performed. At block 530, if it is determined if pin terminals (i.e., one or a set of pins 210) remain without an assignment of a pin constraint 560. If not, then the check at block 520 is repeated. If there is at least one pin terminal without an assignment of a pin constraint 560, then the processes at block 540 are performed.

At block 540, the processes include obtaining properties of the net 400, the pin terminal, and the cell 125. Assigning a pin constraint 560 to the pin terminal, at block 550, refers to selecting from an existing look up table of pin constraints 560. The table of pin constraint 560 is predefined along with a corresponding table of resistance and capacitance (RC) entries.

An exemplary pin constraint 560 is shown. As indicated, the pin constraint 560 is modified from prior pin constraint naming conventions such that cell properties are encoded in the name along with net 400 and, more specifically, UL properties. The properties of the cell 125 that are part of the pin constraint 560 include the pin terminal type (i.e., input or output), the layer of the pins 210 (e.g., the first metal layer, M1), the width of the pins 210 (e.g., in micrometers (microns)), and the number of pins 210 (i.e., the number of must-connect pins). The properties of the UL that are part of the pin constraint 560 include the layer 205 identification, the minimum width according to the wire code at the UL, and the constraint subgroup property (e.g., 0, 1, 2) according to the wire code, which indicates the strength of the via mesh 200 for the cell 125.

As previously noted, the processes shown in FIG. 5 may be performed at any time. The pin constraint 560 that is assigned at block 550 may not correspond with a via mesh specification 250 that is part of the library of universally routable via meshes 200. For example, none of the via meshes 200 may be compatible with a width of the pins 210 that is 0.020 microns. FIG. 6 describes the processes involved in optimizing a design of the integrated circuit 920. When the pin constraint 560 corresponding with a selected net 400 has a corresponding universally routable via mesh 200 based on the library entries, then the optimization process benefits from improved accuracy in timing analysis, as discussed.

FIG. 6 is a process flow of a method 600 of selecting a universally routable via mesh 200 as part of an optimization process according to one or more embodiments of the invention. The optimization process refers to the process of adjusting the design of the integrated circuit 920 iteratively to ensure that timing requirements are met. At block 610, the processes include selecting or changing the properties of the net 400 and/or the source or sink cell 125 (i.e., the cell 125 with the input or output terminals). These selections define the properties that make up the pin constraint 560, as indicated in FIG. 5.

At block 620, retrieving a pin constraint 560 that corresponds with the properties selected at block 610 includes determining if that pin constraint 560 corresponds with a universally routable via mesh specification 250 from the library. Retrieving the pin constraint 560 is based on matching the specifications defined at block 610 based on the nomenclature of the pin constraints 560 that is discussed with reference to FIG. 5. This same nomenclature also allows a determination of whether there is a match with a universally routable via mesh specification 250 stored in the library, as also discussed with reference to FIG. 5. If the pin constraint 560 that is retrieved at block 620 does not have a corresponding universally routable via mesh specification 250, then the pin terminals of the cell 125 are connected to the top layer without the redundancy and corresponding decrease in resistance provided by a via mesh 200. The exemplary embodiment, in which the pin constraint 560 retrieved at block 620 has a corresponding via mesh specification 250 in the library, is considered. In this case, the timing analysis at block 630 is improved, as discussed.

At block 630, performing timing analysis includes considering the via mesh 200, unlike prior optimization processes. This is because, rather than global routes, a specific via mesh 200 and corresponding resistance and capacitance (RC) entry may be used in the timing analysis. A check is done, at block 640, of whether some paths have negative slack (i.e., timing that does not meet the requirement). If so, then a check is done, at block 650, of whether another optimization iteration may be added. If so, then the processes beginning at block 610 are repeated. If the check at block 640 indicates that none of the paths have negative slack (i.e., all paths meet timing requirements) or if another optimization is not possible according to the check at block 650, then the processes end.

In general, electromigration is the movement of atoms based on the flow of current. In some cases, high current densities can cause deposits or vacancies in a metal wire, such as straps 220, that can lead to shorts or opens in the via mesh 200. In order to address the problem of electromigration, the dimensions of existing wires in the via mesh 200 can be adjusted and/or additional wires can be added to the via mesh 200.

In exemplary embodiments, after the placement and routing of the vias and pins, the design of the integrated circuit 920 may require timing or electromigration (EM) adjustments to be manufacturable. For example, the design of the integrated circuit 920 may require the enhancement of the via meshes 200 by adding via mesh straps 220 beyond those found in the universally routable via mesh specification 250 in order to provide a design of the integrated circuit 920 that fixes the timing or EM errors. Currently, the modification of via meshes 200 to correct the timing or EM errors are manually performed.

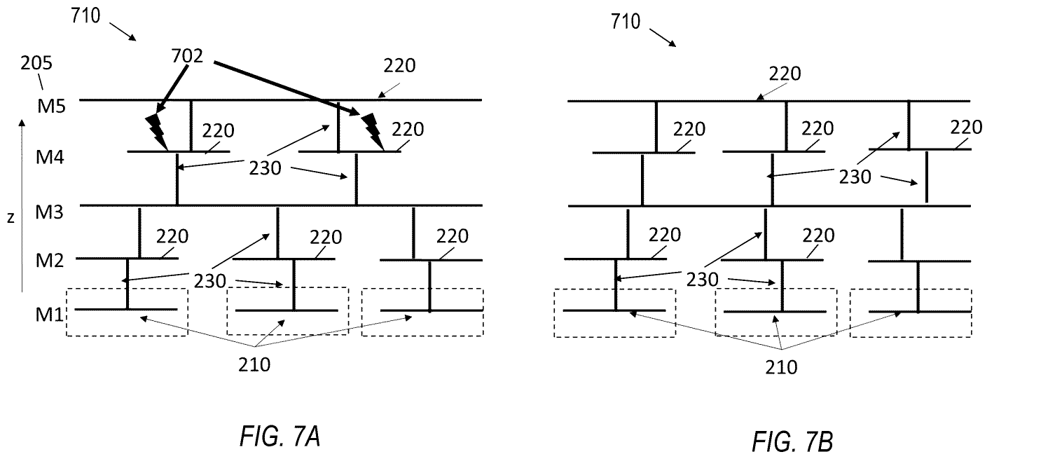

Referring now to FIGS. 7A and 7B, representations of a via mesh specification for an exemplary via mesh before and after the optimization of the via mesh specification according to one or more embodiments of the invention are respectively shown. FIG. 7A illustrates a first via mesh specification 710 that includes a plurality of pins 210, straps 220 and vias 230. The first via mesh specification 710 also includes one or more areas 702 that have been identified as having timing or electromigration failures. As illustrated, the areas 702 are identified as being the straps 220 located on the M4 layer 205. In exemplary embodiments, the areas 702 are identified based on a simulated operation of the integrated circuit including a via mesh built according to the first via mesh specification 700. In exemplary embodiment, a computer aided design tool is configured to simulate the operation of the integrated circuit and to identify the areas 702 that include electromigration or timing issues. Based on the identification of areas 702 in the first via mesh specification 700, a new via mesh specification 710 is created, as shown in FIG. 7B, that includes three straps 220 on the M4 layer. In exemplary embodiments, once the new via mesh specification 710 is created it is provided to a router, which will attempt to build a new via mesh based on the new via mesh specification 710.

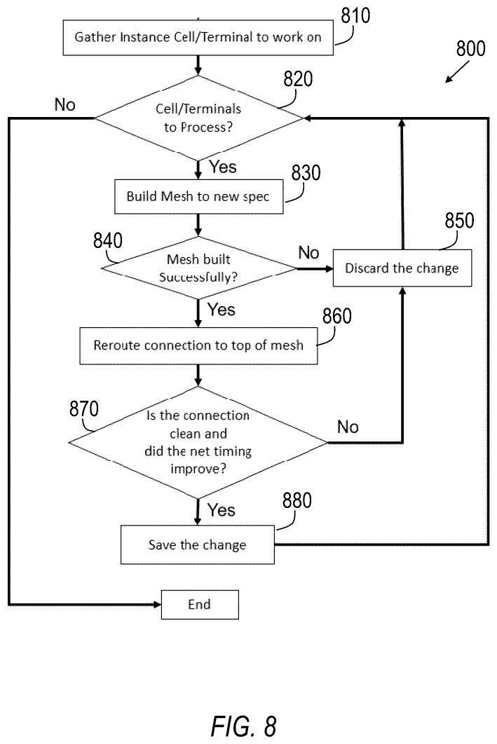

Referring now FIG. 8, a process flow of a method 800 of optimizing a via mesh specification according to one or more embodiments of the invention is shown. As shown at block 810, the method 800 includes identifying one or more cell terminals of an integrated circuit design to have their via meshes enhanced. In exemplary embodiments, the one or more cell terminals are identified based on a simulated operation of the integrated circuit. In exemplary embodiment, a computer aided design tool is configured to simulate the operation of the integrated circuit and to identify one or more cell terminals that include electromigration or timing issues. In exemplary embodiments, a list of cell terminal that include electromigration or timing issues is output by the computer aided design tool based on the simulation of the operation of the integrated circuit.

Next, as shown at decision block 820, it is determined whether any of the identified cell terminals remain to be processed. If so, the method 800 proceeds to block 830 and a new via mesh specification is created for one of the identified cell terminals. In exemplary embodiments, the new via mesh specification for the cell terminal can be formulated in various ways. For example, the new via mesh specification may include adding one or more new straps to identified layers of the via mesh specification or changing the dimensions of the existing straps on one or more layers of the via mesh specification.

In exemplary embodiments, the new via mesh specification that is created may is not be guaranteed to be built by a router (i.e., the new via mesh specification is not created based on existing rules that ensure the that a via mesh will be able to be built by the router). Once the new mesh specification has been created, the new mesh specification is provided to a router that will either create a new design of the integrated circuit with a new via mesh based on the new mesh specification or the router will return an indication that the new mesh specification can not be built successfully. At decision block 840, the method 800 includes determining whether the new mesh specification can be built successfully (i.e., did the router return an error). If the new mesh specification can not be built successfully, the method 800 proceeds to block 850 and the change to the mesh specification for the identified cell terminal is discarded. Otherwise, if the new mesh specification can be built successfully, the method 800 proceeds to block 860 and the connections to the top of the new via mesh built based on the new mesh specification are routed to ensure that the new via mesh properly connects to the other nets in the integrated circuit design. In exemplary embodiments, rebuilding the via mesh by the router may result in the top of the via mesh being moved, which can introduce an open that needs to be resolved (i.e., a strap or via on the top of the mesh may no longer properly connect to an existing net in the circuit design). The top of the via mesh can change based on the geometry of the top layer of the via mesh being modified or based on a change in the height of the via mesh.

Next, as shown at decision block 870, the method 800 includes determining performing a design rule check and timing check on the updated design of the integrated circuit, which includes the new via mesh and any changes required to ensure proper connections between the new via mesh and other nets. For example, rerouting connections between the top of the new via mesh and other nets may introduce new issues, such as timing issues, or may further degrade existing issues by lengthening wires connecting the nets to the new via mesh. If no design rule check or timing degradations are present in the integrated circuit design having the new via mesh, the method 800 proceeds to block 880 and the integrated circuit design having the new via mesh is saved. Otherwise, the method 800 proceeds to block 850 and the changes to the integrated circuit design are discarded.

In exemplary embodiments, prior to making changes on the net, the via mesh and net wires are captured to restore if issues are found. The discard removes any of the changes and reverts the via mesh and connection to the original state. However, if there are not any issues during the rerouting, the change is saved to persist for future optimizations.

In exemplary embodiments, a method for optimizing a mesh specification for an integrated circuit includes obtaining, using a processor, a first mesh specification for a cell within an integrated circuit. The first mesh specification defining one or more straps on each layer above a first layer, which includes one or more pins that form a pin terminal, to a top layer that connects the cell to a net for interconnection of the cell with one or more other cells, and the via mesh specification also including one or more vias that interconnect adjacent ones of the layers. The first mesh specification may be created using the methods shown in FIGS. 3-6.

Next, once a design for the integrated circuit including a first mesh specification has been obtained, the method includes identifying, using the processor based on a simulation of a first via mesh built based on the first via mesh specification, one or more portions of the first mesh specification for enhancement. The portions of the first mesh specification that are identified for enhancement correspond to portions of the first via mesh that are subject to timing and/or electromigration failures during the simulation of the first via mesh. The method also includes generating, a second mesh specification for the cell. The second mesh specification is different from the first mesh specification. In one embodiment, the height of the second mesh specification is greater than a height of first mesh specification. In another embodiment, at least one metal layer of the second mesh specification includes a greater number of straps than a corresponding metal layer of the first mesh specification. In a further embodiment, the second mesh specification for the cell includes an increase in a width of at least one of the one or more straps on the metal layer.

The method also includes generating a second via mesh based on the second via mesh specification and updating a design of the integrated circuit by replacing the first via mesh with the second via mesh and connecting a top layer of the second via mesh to the net. Once the design of the integrated circuit has been updated, the integrated circuit design is subjected to design rule checks and timing checks. Based on a determination that the updated design of the integrated circuit passes both the timing checks and the design rule checks, the updated design of the integrated circuit is saved. However, based on a determination that the updated design of the integrated circuit does not pass one or more of the timing and design rule check, discarding the updated design of the integrated circuit and reverting the design of the integrated circuit to include the first via mesh.

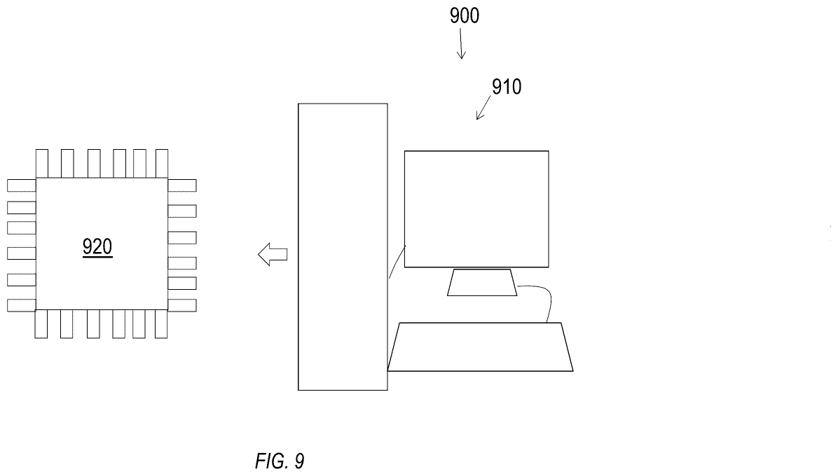

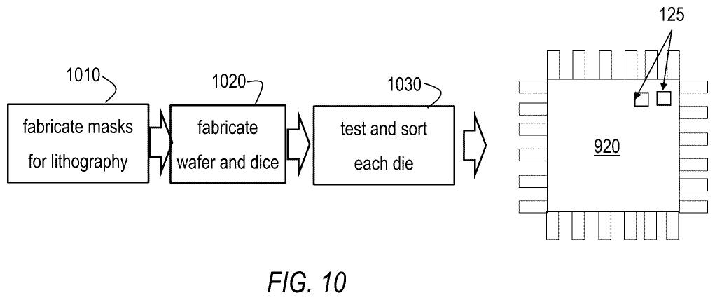

FIG. 9 is a block diagram of a system 900 to perform circuit design optimization according to one or more embodiments. The system 900 includes processing circuitry 910 used to generate the circuit design that is ultimately fabricated into an integrated circuit 920. The steps involved in the fabrication of the integrated circuit 920 are well-known and briefly described herein. Once the physical layout is finalized, based, in part, on the circuit design optimization according to one or more embodiments, the finalized physical layout is provided to a foundry. Masks are generated for each layer of the integrated circuit based on the finalized physical layout. Then, the wafer is processed in the sequence of the mask order. The processing includes photolithography and etch. This is further discussed with reference to FIG. 10.

Particularly, FIG. 10 is a flow diagram of a method of fabricating an integrated circuit according to one or more embodiments. Once the physical design data is obtained, based, in part, on performing circuit design optimization as described herein, the integrated circuit 920 can be fabricated according to known processes that are generally described with reference to FIG. 9. Generally, a wafer with multiple copies of the final design is fabricated and cut (i.e., diced) such that each die is one copy of the integrated circuit 920. At block 1010, the processes include fabricating masks for lithography based on the finalized physical layout. At block 1020, fabricating the wafer includes using the masks to perform photolithography and etching. Once the wafer is diced, testing and sorting each die is performed, at block 1030, to filter out any faulty die.

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

One or more of the methods described herein can be implemented with any or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A computer-implemented method comprising:
obtaining, using a processor, a first mesh specification for a cell within an integrated circuit, the first mesh specification defining one or more straps on each layer above a first layer, which includes one or more pins that form a pin terminal, to a top layer that connects the cell to a net for interconnection of the cell with one or more other cells, and the via mesh specification also including one or more vias that interconnect adjacent ones of the layers;
identifying, using the processor based on a simulation of a first via mesh built based on the first via mesh specification, one or more portions of the first mesh specification for enhancement;
generating, by the processor, a second mesh specification for the cell, wherein the second mesh specification is different from the first mesh specification;
generating, by the processor, a second via mesh based on the second via mesh specification;
updating, by the processor, a design of the integrated circuit by replacing the first via mesh with the second via mesh and connecting a top layer of the second via mesh to the net;
based on a determination that the updated design of the integrated circuit passes a timing and design rule check, saving the updated design of the integrated circuit.

2. The computer-implemented method according to claim 1, further comprising based on a determination that the updated design of the integrated circuit does not pass one or more of the timing and design rule checks, discarding the updated design of the integrated circuit and reverting the design of the integrated circuit to include the first via mesh.

3. The computer-implemented method according to claim 1, wherein the one or more portions of the first mesh specification for enhancement include one or more straps on a metal layer that experience electromigration failure.

4. The computer-implemented method according to claim 3, wherein the second mesh specification for the cell includes an increased number of straps on the metal layer.

5. The computer-implemented method according to claim 3, wherein the second mesh specification for the cell includes an increase in a width of at least one of the one or more straps on the metal layer.

6. The computer-implemented method according to claim 1, wherein generating the second mesh specification for the cell includes determining whether the second via mesh can be built based on the second mesh specification.

7. The computer-implemented method according to claim 1, wherein a height of the second mesh specification is greater than a height of first mesh specification.

8. The computer-implemented method according to claim 1, wherein at least one metal layer of the second mesh specification includes a greater number of straps than a corresponding metal layer of the first mesh specification.

9. A system comprising:
a memory having computer readable instructions; and
one or more processors for executing the computer readable instructions, the computer readable instructions controlling the one or more processors to perform operations comprising:
obtaining a first mesh specification for a cell within an integrated circuit, the first mesh specification defining one or more straps on each layer above a first layer, which includes one or more pins that form a pin terminal, to a top layer that connects the cell to a net for interconnection of the cell with one or more other cells, and the via mesh specification also including one or more vias that interconnect adjacent ones of the layers;
identifying, based on a simulation of a first via mesh built based on the first via mesh specification, one or more portions of the first mesh specification for enhancement;
generating a second mesh specification for the cell, wherein the second mesh specification is different from the first mesh specification;
generating a second via mesh based on the second via mesh specification;
updating a design of the integrated circuit by replacing the first via mesh with the second via mesh and connecting a top layer of the second via mesh to the net;
based on a determination that the updated design of the integrated circuit passes a timing and design rule check, saving the updated design of the integrated circuit.

10. The system according to claim 9, wherein the operations further comprise discarding the updated design of the integrated circuit and reverting the design of the integrated circuit to include the first via mesh based on a determination that the updated design of the integrated circuit does not pass one or more of the timing and design rule checks.

11. The system according to claim 9, wherein the one or more portions of the first mesh specification for enhancement include one or more straps on a metal layer that experience electromigration failure.

12. The system according to claim 11, wherein the second mesh specification for the cell includes an increased number of straps on the metal layer.

13. The system according to claim 11, wherein the second mesh specification for the cell includes an increase in a width of at least one of the one or more straps on the metal layer.

14. The system according to claim 9, wherein generating the second mesh specification for the cell includes determining whether the second via mesh can be built based on the second mesh specification.

15. The system according to claim 9, wherein a height of the second mesh specification is greater than a height of first mesh specification.

16. The system according to claim 9, wherein at least one metal layer of the second mesh specification includes a greater number of straps than a corresponding metal layer of the first mesh specification.

17. A computer program product comprising a computer readable storage medium having program instructions embodied therewith, the program instructions executable by a processor to cause the processor to perform operations comprising:
obtaining a first mesh specification for a cell within an integrated circuit, the first mesh specification defining one or more straps on each layer above a first layer, which includes one or more pins that form a pin terminal, to a top layer that connects the cell to a net for interconnection of the cell with one or more other cells, and the via mesh specification also including one or more vias that interconnect adjacent ones of the layers;
identifying, based on a simulation of a first via mesh built based on the first via mesh specification, one or more portions of the first mesh specification for enhancement;
generating a second mesh specification for the cell, wherein the second mesh specification is different from the first mesh specification;
generating a second via mesh based on the second via mesh specification;
updating a design of the integrated circuit by replacing the first via mesh with the second via mesh and connecting a top layer of the second via mesh to the net;
based on a determination that the updated design of the integrated circuit passes a timing and design rule check, saving the updated design of the integrated circuit.

18. The computer program product according to claim 17, wherein the operations further comprise discarding the updated design of the integrated circuit and reverting the design of the integrated circuit to include the first via mesh based on a determination that the updated design of the integrated circuit does not pass one or more of the timing and design rule checks.

19. The computer program product according to claim 17, wherein the one or more portions of the first mesh specification for enhancement include one or more straps on a metal layer that experience electromigration failure.

20. The computer program product according to claim 19, wherein the second mesh specification for the cell includes an increased number of straps on the metal layer.
